(19) United States
(12) Patent Application Publication
(10) Pub. No.: US 2014/0016007 A1
(43) Pub. Date: Jan. 16, 2014

(54) READOUT CIRCUIT, SOLID-STATE IMAGING APPARATUS, AND METHOD FOR DRIVING READOUT CIRCUIT

(71) Applicant: CANON KABUSHIKI KAISHA, Tokyo (JP)

(72) Inventors: Masanori Ogura, Tokyo (JP); Hideo Kobayashi, Tokyo (JP); Tetsunobu Kochi, Hiratsuka-shi (JP)

(21) Appl. No.: 13/919,810

(22) Filed: Jun. 17, 2013

(30) Foreign Application Priority Data
Jul. 12, 2012 (JP) 2012-156611

(51) Int. Cl. H04N 5/335; H03F 3/45

(52) U.S. Cl. CPC H04N 5/335; H03F 3/45179
USPC 348/300; 348/294; 330/260

(57) ABSTRACT

A readout circuit includes: an amplifier (408); and offset controllers (415 and 416) configured to set an output offset voltage of the amplifier, wherein the readout circuit operates in first and second modes, in the first mode, a first voltage, and thereafter a second voltage lower than the first voltage, are input into the amplifier, in the second mode, a third voltage, and thereafter a fourth voltage higher than the third voltage, are input into the amplifier, and the offset controller switches the output offset voltage of the amplifier, between the first and second modes.

### BACKGROUND OF THE INVENTION

1. Field of the Invention

The present disclosure relates to a readout circuit, a solid-state imaging apparatus, and a method for driving a readout circuit.

2. Description of the Related Art

A CMOS image sensor and a CCD image sensor include a pixel which includes a photoelectric conversion element, and a peripheral circuit which includes a readout circuit for reading out a signal that has been generated by photoelectric conversion in the pixel. In particular, CMOS image sensors are becoming to have higher functionalities due to having various modes. For instance, there is a CMOS image sensor which can switch resolution or a read out speed. As for image sensors associated with the above, there is a CMOS image sensor in which an input voltage range of the readout circuit changes and an order of input voltages change, according to the modes.

In Japanese Patent Application Laid-Open No. 2010-74784, a solid-state imaging apparatus is described which includes a photoelectric conversion element, a resetting element for resetting the photoelectric conversion element, and a plurality of clamping capacitors for accumulating electric charges therein which have been generated in the photoelectric conversion element and then have been amplified by an amplifier unit. The solid-state imaging apparatus further includes common nodes which are provided on each of the clamping capacitors and can be connected to the clamping capacitor, a plurality of pixel selecting switches each connected between the clamping capacitor and the common node, and a clamping unit for fixing the common node to a reference voltage. The solid-state imaging apparatus further includes a sampling and holding circuit which is connected to the common node through the clamping unit, and samples and holds electric charges according to the electric charge of the common node. In a first mode, the solid-state imaging apparatus accumulates the output of the amplifier unit according to the amount of an electric charge which has been obtained through photoelectric conversion by the photoelectric conversion element, in the clamping capacitor as a photo signal, and then after the photoelectric conversion element has been reset by a resetting element, accumulates the signal to be output in response to the reset by the amplifier unit, in the clamping capacitor as a reset signal. In a second mode, after the photoelectric conversion element has been reset by the resetting element, the solid-state imaging apparatus accumulates the signal to be output in response to the reset by the amplifier unit, in the clamping capacitor as the reset signal. Next, the solid-state imaging apparatus accumulates the output of the amplifier unit according to the amount of the electric charges which has been obtained through the photoelectric conversion by the photoelectric conversion element in the clamping capacitor as the photo signal to sample and hold the reset signal and a difference between the photo signal and the reset signal.

In the configuration described in Japanese Patent Application Laid-Open No. 2010-74784, in the first mode, the reset signal is input into the clamping capacitor after the photo signal, and in the second mode, the photo signal is input into the clamping capacitor after the reset signal. Accordingly, the potentials which appear in the output of the clamping unit are also different. In the first mode, the output potential of the clamping unit when the photo signal has been input into the clamping unit shall be represented by an output potential 1, and the output potential of the clamping unit when the reset signal has been input into the clamping unit shall be represented by an output potential 2. In addition, in the second mode, the output potential of the clamping unit when the reset signal has been input into the clamping unit shall be represented by an output potential 3, and the output potential of the clamping unit when the reset signal has been input into the clamping unit shall be represented by an output potential 4. Then, the relationship of the magnitude between the output potential 1 and the output potential 2 and the relationship of the magnitude between the output potential 3 and the output potential 4 are reversed. The output potential 2 of the clamping unit in the first mode and the output potential 4 of the clamping unit in the second mode becomes an electric signal which shows the difference between the photo signal and the reset signal, and the magnitude, or the polarity of the output potential 2 and the output potential 4, is reversed.

In this case, even when a dynamic range in which the clamping unit is operated is appropriate in the first mode, the dynamic range becomes narrow in the second mode, and a sufficient dynamic range may not be available. In Japanese Patent Application Laid-Open No. 2010-74784, it is described in FIG. 7 and the second embodiment that reference voltages VC0R1 and VC0R2 to be input into the clamping unit are changed according to the mode, and thereby the dynamic range is appropriately secured. However, in the embodiment, such a case is considered that even when the reference potential VC0R1 or VC0R2 to be input into an amplifier 201 is selected and used so as to suit the mode, the dynamic range cannot still be secured depending on the configuration of an amplifier constituting the clamping unit.

### SUMMARY OF THE INVENTION

According to an aspect of the present invention, a readout circuit comprises: an amplifier; and an offset controller configured to set an output offset voltage of the amplifier, wherein the readout circuit operates in first and second modes, in the first mode, the amplifier inputs a first voltage, and thereafter inputs a second voltage lower than the first voltage, in the second mode, the amplifier inputs a third voltage, and thereafter inputs a fourth voltage lower than the third voltage, and the offset controller switches the output offset voltage of the amplifier, between the first and second modes.

Further features of the present invention will become apparent from the following description of exemplary embodiments with reference to the attached drawings.

### BRIEF DESCRIPTION OF THE DRAWINGS

FIG. 1 is a circuit diagram illustrating a configuration example of a readout circuit.

FIG. 2 is a circuit diagram illustrating a configuration example of an amplifier.

FIGS. 3A and 3B are timing charts for describing an operation of the readout circuit.

FIG. 4 is a circuit diagram of a solid-state imaging apparatus of a first embodiment.

FIG. 5 is a timing chart of the solid-state imaging apparatus of the first embodiment.

FIG. 6 is a timing chart of the solid-state imaging apparatus of the first embodiment.

FIG. 7 is a circuit diagram illustrating a configuration example of the readout circuit of the first embodiment.

FIG. 8 is a circuit diagram of a PC0R controller of the first embodiment.

FIG. 9 is a circuit diagram of a solid-state imaging apparatus of a second embodiment.

FIG. 10 is a timing chart of the solid-state imaging apparatus of the second embodiment.

FIG. 11 is a timing chart of the solid-state imaging apparatus of the second embodiment.

FIG. 12 is a circuit diagram of a solid-state imaging apparatus of a third embodiment.

FIG. 13 is a timing chart of the solid-state imaging apparatus of the third embodiment.

FIG. 14 is a timing chart of the solid-state imaging apparatus of the third embodiment.

FIG. 15 is a circuit diagram of a solid-state imaging apparatus of a fourth embodiment.

FIG. 16 is a timing chart of the solid-state imaging apparatus of the fourth embodiment.

FIG. 17 is a timing chart of the solid-state imaging apparatus of the fourth embodiment.

FIG. 18 is a circuit diagram of a solid-state imaging apparatus of a fifth embodiment.

FIG. 19 is a circuit diagram illustrating a configuration example of an amplifier of the fifth embodiment.

### DESCRIPTION OF THE EMBODIMENTS

Preferred embodiments of the present invention will now be described in detail in accordance with the accompanying drawings.

### First Embodiment

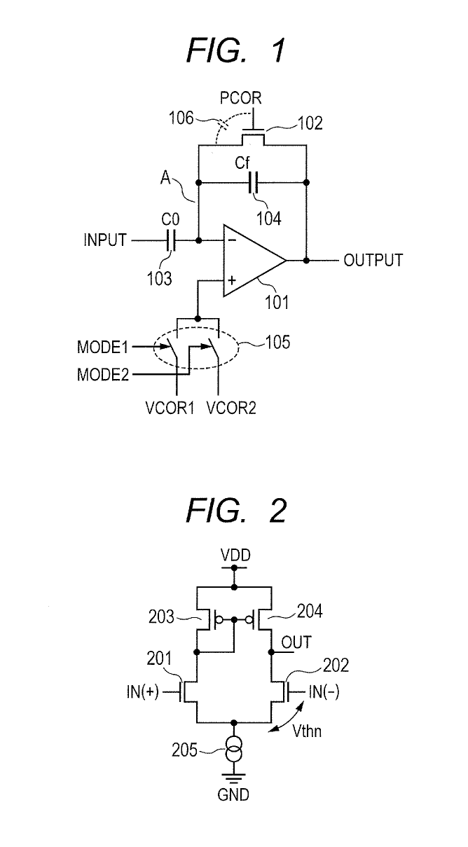

FIG. 1 is a view illustrating a configuration example of a readout circuit according to a first embodiment of the present invention. Hereafter, the case will be described in which an appropriate dynamic range cannot be secured depending on an amplifier 101, even when input reference voltages VC0R1 and VC0R2 are selected according to the mode. The readout circuit has a clamping unit. The amplifier 101, a switch 102, an input capacitor 103, a feedback capacitor 104, and a switch 105 for switching between the reference voltages VC0R1 and VC0R2 are shown. A capacitance value of the input capacitor 103 is C0, and a capacitance value of the feedback capacitor 104 is Cf. When a first mode signal MODE1 becomes a high level, the reference voltage VC0R1 is input into an input terminal (+) of the amplifier 101, and when a second mode signal MODE2 becomes a high level, the reference voltage VC0R2 is input into the input terminal (+) of the amplifier 101. The input signal of the readout circuit is input into an input terminal (−) of the amplifier 101 through the input capacitor 103. An output signal of the readout circuit is an output signal of the amplifier 101.

FIG. 2 illustrates a differential amplifier which constitutes the amplifier 101 in FIG. 1. NMOS transistors 201 and 202, PMOS transistors 203 and 204, and a constant current source 205 are shown. The differential amplifier can be configured with comparatively few elements, and is also little influenced by variations of a power source potential and a ground potential.

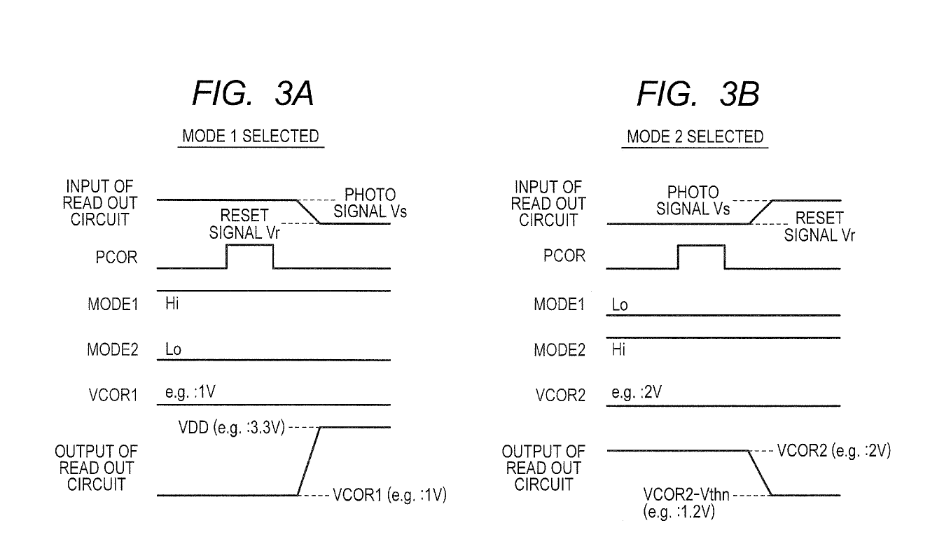

FIGS. 3A and 3B are timing charts illustrating a method for driving a readout circuit of FIG. 1. FIG. 3A is a timing chart when a first mode signal MODE1 is a high level. When a signal PC0R becomes a high level, a photo signal Vs which is an input signal of the readout circuit is clamped at an input reference voltage VC0R1, in the state in which the input terminal (−) and the output terminal of the amplifier 101 are short-circuited, and an output signal of the readout circuit becomes the reference voltage VC0R1. Thereafter, after the signal PC0R is set at a low level, and a reset signal Vr which is an input signal of the readout circuit is input, a voltage of [−(Vr−Vs)×Cf/C0+VC0R1] is output to the output of the readout circuit. In this case, the upper limit of the output signal of the readout circuit can be increased up to a power source voltage VDD which is given to the amplifier 101. This is because the output terminal OUT of the amplifier 101 is connected to a drain of the PMOS transistor 204, and the output signal can be varied up to the power source voltage VDD of a source potential of the PMOS transistor 204. In this case, the input reference voltage VC0R1 can be set at VDD/2 or less. The dynamic range of the signal sent from the output terminal OUT of the amplifier 101 is between the reference voltage VC0R1 and the power source voltage VDD, and accordingly if the reference voltage VC0R1 has been set at a low value, the dynamic range can be widened.

FIG. 3B is a timing chart when the second mode signal MODE2 is in a high level. When the signal PC0R becomes a high level, the input terminal (−) and the output terminal of the amplifier 101 become a state of being short-circuited, the reset signal Vr which is the input signal of the readout circuit is clamped at input reference voltage VC0R2, and the output signal of the readout circuit becomes the reference voltage VC0R2. After that, the signal PC0R is set at a low level, and then when the photo signal Vs which is the input signal of the readout circuit is input, the voltage of [−(Vs−Vr)×Cf/C0+VC0R2] is output to the output of the readout circuit. In this case, the lower limit of the output signal of the readout circuit can be lowered only to a value which is lower than a gate voltage of the NMOS transistor 202 of the amplifier 101 by a threshold voltage Vthn. This is because the output terminal OUT of the amplifier 101 is connected to the drain of the NMOS transistor 202, and the output signal can be varied only to a source potential of the NMOS transistor 202, which is specifically −Vthn (gate voltage of NMOS transistor 202). In addition, in the case of the readout circuit in FIG. 1, a gate voltage IN (+) of the NMOS transistor 201 and a gate voltage IN (−) of the NMOS transistor 202 operate as in an imaginary short-circuited state. Because of this, the same voltage as the reference voltage VC0R2 which is input into the gate of the NMOS transistor 201 results in being input into the gate of the NMOS transistor 202. Accordingly, the output terminal OUT of the amplifier 101 can be lowered only to the voltage VC0R2−Vthn. In this case, the reference voltage VC0R2 can be set at VDD/2 or more. This is because when the reference voltage VC0R2 is set at an excessively low value, the voltage suppresses operating regions of the NMOS transistors 201 and 202 and the constant current source 205. However, the dynamic range of the signal sent from the output terminal OUT of the amplifier 101 is a range between the reference voltage VC0R2 and the voltage VC0R2−Vthn. Specifically, the dynamic range becomes Vthn, and even when the reference voltage VC0R2 is changed, the dynamic range is not improved.

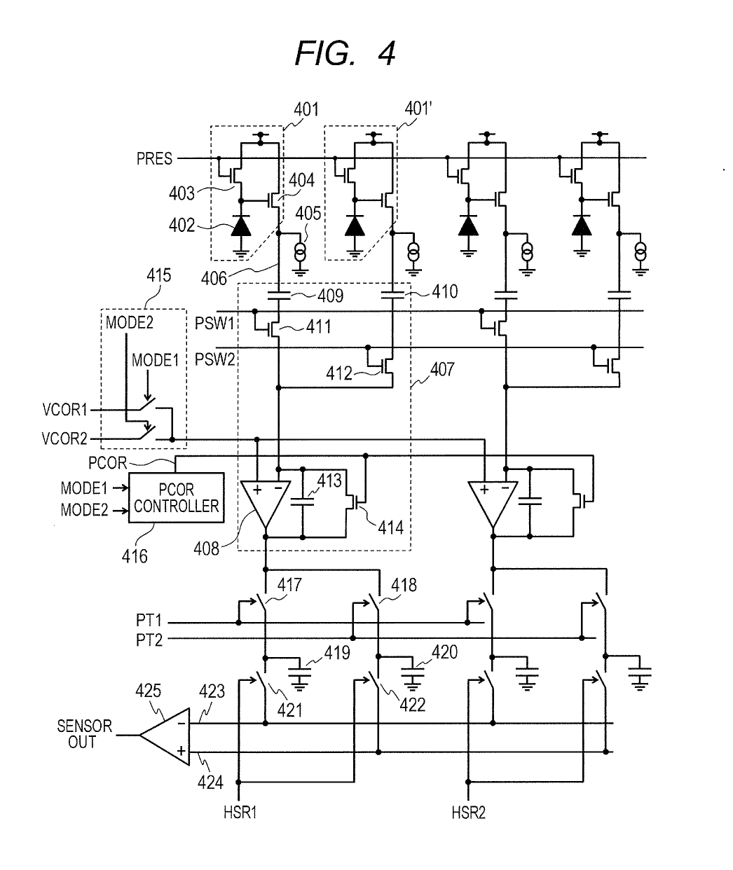

FIG. 4 is a view illustrating a configuration example of a solid-state imaging apparatus which has a readout circuit 407 according to the first embodiment of the present invention. A plurality of pixels 401 and 401′ are arrayed. A photo detector 402, a reset transistor 403, a source follower transistor 404, and a constant current load 405 are shown. A pixel signal output line 406 transmits the signal of the pixel 401 therethrough to the readout circuit 407. A plurality of the readout circuits 407 are arrayed each of which corresponds to the readout circuit in FIG. 1. An amplifier 408 corresponds to the amplifier 101 in FIG. 1. Input capacitors 409 and 410 each correspond to the input capacitor 103 in FIG. 1, and correspond to the outputs of the pixels 401 and 401′, respectively. The input capacitors 409 and 410 each input a signal into the input terminal (−) of the amplifier 408 by capacitive coupling. Switches 411 and 412 connect the input capacitors 409 and 410 with the amplifier 408, respectively. A feedback capacitor 413 corresponds to the feedback capacitor 104 in FIG. 1. The feedback capacitor 413 is provided between the output terminal and the input terminal (−) of the amplifier 408. An initializing switch 414 corresponds to the switch 102 in FIG. 1, and short-circuits the input terminal (−) and the output terminal of the amplifier 408. The initializing switch 414 is the switch for short-circuiting the output terminal and the input terminal (−) of the amplifier 408. A switching device (offset controller) 415 corresponds to the switch 105 in FIG. 1, and switches a reference voltage to be input into the input terminal (+) of the amplifier 408 between VC0R1 and VC0R2, according to mode signals MODE 1 and MODE 2. Switches 417 and 418, capacitors 419 and 420, switches 421 and 422, common output lines 423 and 424, and a final stage output amplifier 425 are shown. A PC0R controller (offset controller) 416 outputs the signal PC0R according to the mode signals MODE1 and MODE2.

In FIG. 4, one readout circuit 407 corresponds to the two pixels 401 and 401′. The one readout circuit 407 can read out the pixel signals of the two pixels 401 and 401′ in time series. Thereby, there are such merits that the number of the readout circuits 407 can be reduced, and the chip area of the solid-state imaging apparatus can be reduced.

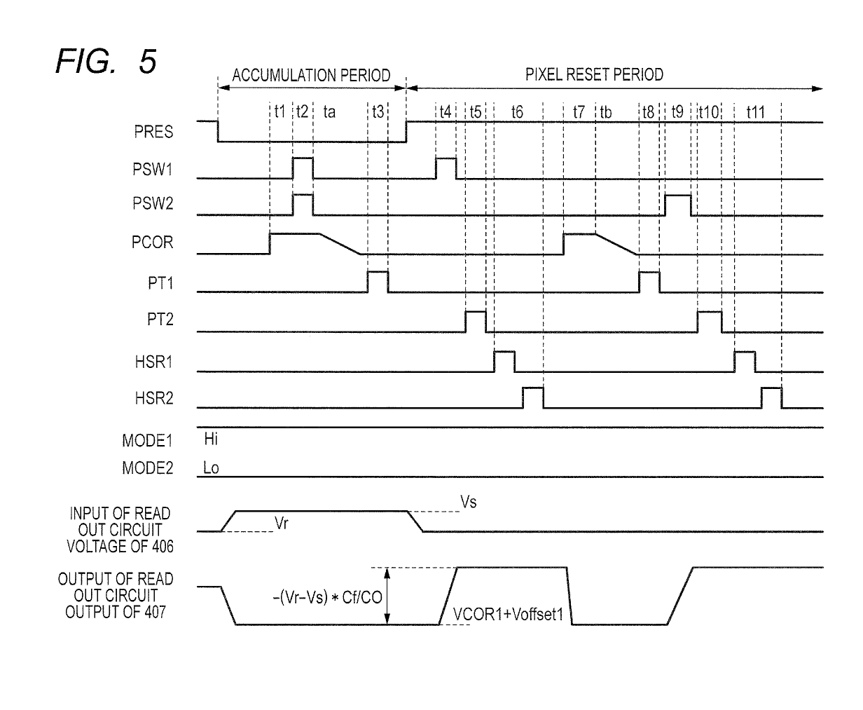

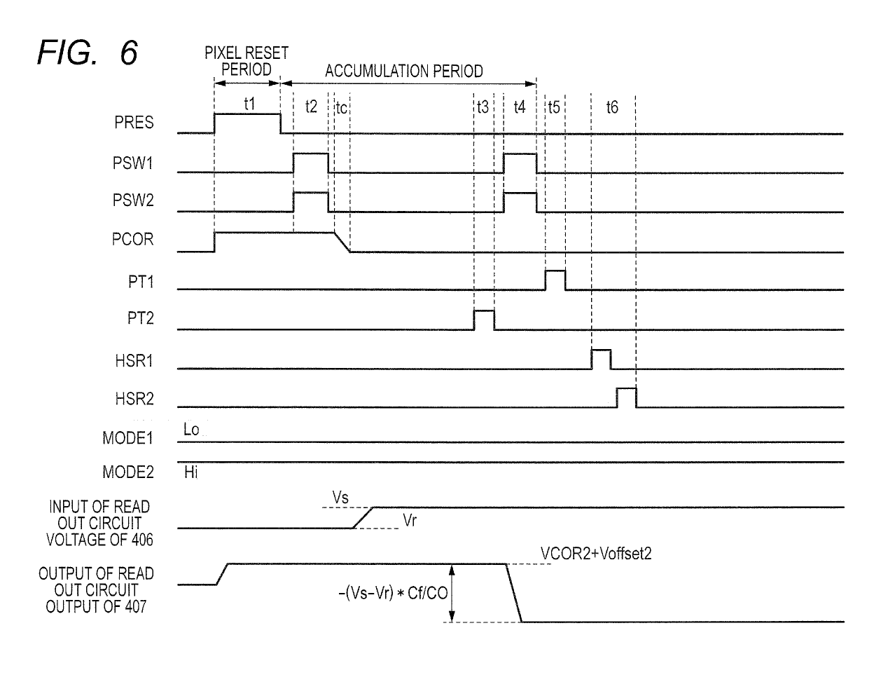

FIG. 5 and FIG. 6 are timing charts each illustrating an operation example of the solid-state imaging apparatus in FIG. 4. Firstly, a method will be described below with reference to FIG. 5, as the first mode in which the readout circuit 407 reads out the signals of the two pixels 401 and 401′ in time series. In the first mode, the amplifier 408 inputs a photo signal (first voltage) Vs in a period t2, and then inputs a pixel reset signal Vr (second voltage) which is lower than the photo signal Vs, in periods t4 and t9, through the pixel signal output line 406. Because the first mode signal MODE1 becomes a high level and the second mode signal MODE2 becomes a low level, the switching device 415 outputs the reference voltage VC0R1 to the input terminal (+) of the amplifier 408. Firstly, the readout circuit 407 reads out the signal of the pixel 401. In an accumulation period, the photo detector 402 generates a photo signal by photoelectric conversion. The source follower transistor 404 amplifies the photo signal which has been generated by the photo detector 402, and outputs the photo signal Vs to the pixel signal output line 406. In the period t1, the signal PC0R becomes a high level, and the initializing switch 414 is turned on and initializes the readout circuit 407. At this time, the photo signal Vs is input into the input capacitors 409 and 410. In the state, the process proceeds to the period t2. Then, signals PSW1 and PSW2 become a high level, and switches 411 and 412 are turned on. Here, the photo signals Vs of the pixels 401 and 401′ are clamped at the reference voltage VC0R1. In the first mode, the first mode signal MODE1 becomes a high level, the second mode signal MODE2 becomes a low level, and the solid-state imaging apparatus in FIG. 4 operates in response to the first mode. The read out timing for the pixels 401 and 401′, the reference voltage VC0R1 to be supplied to the readout circuit 407, and the like, are set, for instance. After that, in a period t3, a signal PT1 becomes a high level, the switch 417 is turned on, and the capacitor 419 holds the potential of [VC0R1+Voffset1] by sampling and holding. A potential Voffset1 is an offset potential peculiar to the readout circuit 407, and varies also depending on an element constituting the amplifier 408 and the driving method.

Next, in a pixel reset period, a signal PRES becomes a high level, and the reset transistor 403 is turned on to reset the photo detector 402. Then, the photo detector 402 outputs a pixel reset signal. The source follower transistor 404 amplifies the pixel reset signal of the photo detector 402, and outputs the pixel reset signal Vr to the pixel signal output line 406. In a period t4, a signal PSW1 becomes a high level, and a switch 411 is turned on. Then, the input capacitor 409 is connected to the input terminal (−) of the amplifier 408, and inputs the pixel reset signal Vr to the input terminal (−) of the amplifier 408. In the output terminal of the amplifier 408, the output voltage of [−(Vr−Vs)×Cf/C0+VC0R1+Voffset1] appears. Here, Cf represents the capacitance value of the feedback capacitor 413, and C0 represents the capacitance value of each of the input capacitors 409 and 410. In a period t5, a signal PT2 becomes a high level, and a switch 418 is turned on. Then, the capacitor 420 samples and holds the voltage of [−(Vr−Vs)×Cf/C0+VC0R1+Voffset1]. After that, in a period t6, signals HSR1 and HSR2 sequentially become a high level, and switches 421 and 422 are turned on. Then, the voltages of the capacitors 419 and 420 are output to common output lines 423 and 424, respectively. An output amplifier 425 outputs a difference signal of the voltages of the common output lines 423 and 424.

Subsequently, a method for reading out the pixel signal of the pixel 401′ will be described below. In a period t7, the signal PC0R becomes a high level, and the initializing switch 414 is turned on and initializes the readout circuit 407. After that, in a period t8, the signal PT1 becomes a high level, the switch 417 is turned on, and the capacitor 419 holds the potential of [VC0R1+Voffset1] by sampling and holding. After that, in a period t9, a signal PSW2 becomes a high level, and a switch 412 is turned on. Then, in the output terminal of the amplifier 408, the output voltage of [−(Vr−Vs)×Cf/C0+VC0R1+Voffset1] appears. In a period t10, the signal PT2 becomes a high level, and the switch 418 is turned on. Then, the capacitor 420 holds the voltage of [−(Vr−Vs)×Cf/C0+VC0R1+Voffset1] by sampling and holding. After that, in a period t11, signals HSR1 and HSR2 sequentially become a high level, and switches 421 and 422 are turned on. Then, the voltages of the capacitors 419 and 420 are output to the common output lines 423 and 424, respectively. The output amplifier 425 outputs a difference signal of the voltages of the common output lines 423 and 424. In this first mode, a pixel reset noise having no correlation is contained in the photo signal Vs and the pixel reset signal Vr, and accordingly the readout circuit 407 cannot remove the pixel reset noise. For information, the pixel reset noise can be removed in a second mode which will be described later. In addition, the offset potential Voffset1 can be removed by the difference of the output amplifier 425. In such a procedure, the solid-state imaging apparatus individually reads out the signals of the pixels 401 and 401′ in time series, by using the readout circuit 407.

Next, a method will be described below as the second mode in which the readout circuit 407 adds and reads out the signals of the two pixels 401 and 401′. In the second mode, the first mode signal MODE1 becomes a low level, and the second mode signal MODE2 becomes a high level. Then, the switching device 415 outputs reference voltage VC0R2 to the input terminal (+) of the amplifier 408. In this case, the pixel reset signal Vr is first input into the readout circuit 407, and then the photo signal Vs is input which is the pixel reset signal Vr with a signal corresponding to the quantity of light superimposed thereon. Thereby, the pixel reset noise can be removed. The procedure will be described below with reference to a timing chart in FIG. 6.

FIG. 6 is a timing chart illustrating an operation example in a second mode of a solid-state imaging apparatus in FIG. 4. In the second mode, the amplifier 408 inputs a pixel reset signal (third voltage) Vr in a period t2, and then inputs a photo signal (fourth voltage) Vs which is higher than the pixel reset signal Vr in a period 4, through the pixel signal output line 406. In a period t1 in a pixel reset period, the signal PRES becomes a high level, and the reset transistor 403 is turned on. Then, the photo detector 402 is reset, and outputs a reset signal. The source follower transistor 404 amplifies the reset signal of the photo detector 402, and outputs a pixel reset signal Vr to the pixel signal output line 406. In addition, the signal PC0R becomes a high level, and the initializing switch 414 is turned on and initializes the readout circuit 407. At this time, the pixel reset signal Vr is input into the input capacitors 409 and 410. In the state, the process proceeds to the period t2. Then, the signals PSW1 and PSW2 are turned on, and the switches 411 and 412 are turned on. Here, the pixel reset signals Vr of the pixels 401 and 401′ are clamped at the reference voltage VC0R2. In the second mode, the second mode signal MODE2 becomes a high level, and the solid-state imaging apparatus in FIG. 4 operates in response to the second mode. The read out timing for the pixels 401 and 401′, the reference voltage VC0R2 to be supplied to the readout circuit 407, and the like, are set, for instance. After that, in a period t3 after an accumulation period, the signal PT2 becomes a high level, and the switch 418 is turned on. Then, the capacitor 420 holds the output voltage [VC0R2+Voffset2] of the amplifier 408 by sampling and holding. The potential Voffset2 is an offset potential peculiar to the readout circuit 407, and varies also depending on an element constituting the amplifier 408 and the driving method.

Next, in a period t4, the photo detector 402 outputs a photo signal by photoelectric conversion. The source follower transistor 404 amplifies the photo signal of the photo detector 402, and outputs the photo signal to the pixel signal output line 406. The signals PSW1 and PSW2 become a high level, and the switches 411 and 412 are turned on. Then, the input capacitors 409 and 410 are connected to the input terminal (−) of the amplifier 408. The input terminal (−) of the amplifier 408 inputs the photo signal Vs which is a blend of the photo signals of the two pixels 401 and 401′. Then, in the output terminal of the amplifier 408, the output voltage of [−(Vs−Vr)×Cf/C0+VC0R2+Voffset2] appears. In a period t5, the signal PT1 becomes a high level, and the switch 417 is turned on. Then, the capacitor 419 holds the voltage [−(Vs−Vr)×Cf/C0+VC0R2+Voffset2] by sampling and holding. After that, in a period t6, signals HSR1 and HSR2 sequentially become a high level, and switches 421 and 422 are turned on. Then, the voltages of the capacitors 419 and 420 are output to the common output lines 423 and 424, respectively. The output amplifier 425 outputs a difference signal of the voltages of the common output lines 423 and 424. The offset potential Voffset2 can be removed by the difference of the output amplifier 425. In addition, in the second mode, a pixel reset noise having correlation is contained in the photo signal Vs and the pixel reset signal Vr, and accordingly can be removed by a clamping operation of the readout circuit 407. In the second mode, the polarity of the output signal of the amplifier 408 is reversed to that in the first mode, and accordingly timings are also changed at which the output voltage of the amplifier 408 is sampled and held by the capacitors 419 and 420. Thus, the dynamic ranges of the common output lines 423 and 424 and the output amplifier 425 are controlled so as not to be suppressed.

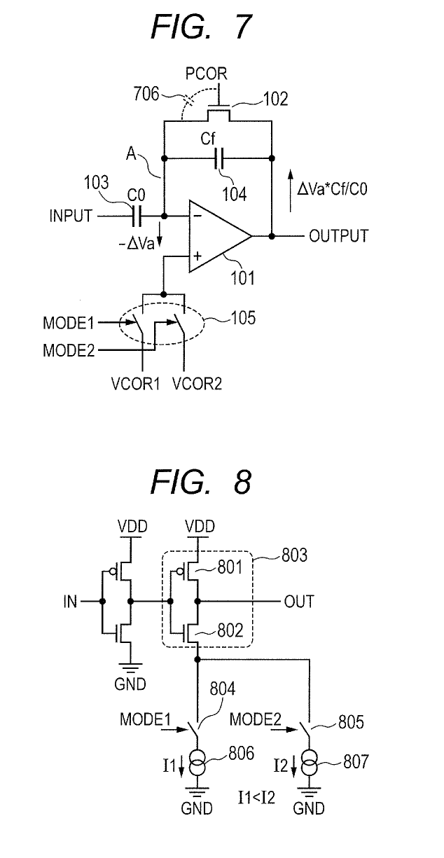

Fall times of the signals PC0R are different between periods ta and tb in the first mode in FIG. 5 and a period tc in the second mode in FIG. 6. A node (A) and the gate of a transistor 102 in FIG. 7 are capacitively coupled by a parasitic capacitance 706 such as a gate overlap capacitance. In FIG. 7, items which are not particularly described here are similar to those in FIG. 1. The change of a potential at the node (A) varies depending on the falling speed of the signal PC0R. The more quickly the signal PC0R falls, the more the voltage (−ΔVa) can be lowered at the node (A). In the first mode, when the voltage capable of being lowered at the node (A) is represented by −ΔVa1, the variation of the output of the amplifier 408 becomes ΔVa1×Cf/C0, and is raised. Similarly, in the second mode, when the voltage capable of being lowered at the node (A) is represented by −ΔVa2, the variation of the output of the amplifier 408 becomes ΔVa2×Cf/C0, and is raised. These variations of the outputs of the amplifier 408 become factors of offset potentials Voffset1 and Voffset1.

In the first mode, the fall periods ta and tb of the signal PC0R are extended, −ΔVa1 is decreased, the variation ΔVa1×Cf/C0 of the output of the amplifier 408 is decreased, and thereby the offset potential Voffset1 is suppressed to a low value. On the other hand, in the second mode, the fall period tc of the signal PC0R is shortened, thereby −ΔVa2 is increased, the quantity to be raised of the variation ΔVa2×Cf/C0 of the output of the amplifier 408 is increased, and the offset potential Voffset2 is increased.

In the present embodiment, the fall period of the signal PC0R is controlled and is changed between the first mode and the second mode. Specifically, a transition period of a control signal PC0R for switching the initializing switch 414 from on to off is different between the first mode and the second mode. In the second mode, the fall period tc of the signal PC0R is shortened.

Thereby, the dynamic range of the output can be widened by the value of ΔVa2ΔCf/C0, and the dynamic range of the output of the amplifier 408 becomes [Vthn+ΔVa2×Cf/C0]. Thus, the dynamic range of the output can be widened. In addition, in the first mode, the fall periods to and tb of the signal PC0R are extended, and ΔVa1 may be approximated to zero. For information, the operation described here is effective in expanding the dynamic range, even in the case where signals of the pixels are not summed up in the second mode, and in the case of such a mode that only the input order of the pixel reset signal Vr and the photo signal Vs is changed which are input into the readout circuit 407.

FIG. 8 is a view illustrating a configuration example of a PC0R controller 416 in FIG. 4. A PMOS transistor 801, an output stage inverter 803, an NMOS transistor 802, switches 804 and 805, and constant current sources 806 and 807 are shown. The constant current sources 806 and 807 are connected between the source of the NMOS transistor 802 of the output stage inverter 803 and the ground potential node, through the switches 804 and 805, respectively. The switches 804 and 805 are turned on/off in response to the mode signals MODE1 and MODE2, respectively, and switch between the constant current sources 806 and 807. The period during which an electric charge of the load in the output terminal OUT is extracted is different between the constant current sources 806 and 807, and the fall period of the signal PC0R is determined by the period. When the constant current passing through the constant current source 806 is represented by I1, and the constant current passing through the constant current source 807 is represented by I2, the constant currents have a relationship of I1<I2. The larger the constant current value becomes, the more quickly the constant current source can lower the output signal PC0R. When the first mode signal MODE1 becomes a high level, the switch 804 is turned on, an electric current I1 passes, and the descending period of the signal PC0R can be extended. In addition, when the second mode signal MODE2 becomes a high level, the switch 805 is turned on, an electric current I2 passes, and the descending period of the signal PC0R can be shortened. Thereby, the fall period tc in the second mode in FIG. 6 can be made shorter than the fall periods to and tb in the first mode in FIG. 5. In FIG. 8, it is also possible to provide a simple wiring connection to the ground potential node in place of the constant current source 807 that is selected in the mode signal MODE2, operate the inverter 803 as a usual inverter, quickly lower the signal PC0R and shorten the period tc. In this case, the fall period tc of the signal PC0R becomes as short as those of other pulses.

A line sensor including one or several rows of pixels is used in an image reading apparatus in a scanner and a copying machine. In the line sensor, it is required to reduce the area of a peripheral circuit including the readout circuit. Accordingly, a rail-to-rail type operational amplifier is unsuitable for a solid-state imaging apparatus like the line sensor, because of having many numbers of elements, though having a wide dynamic range. A readout circuit which corresponds to various modes and has a wide dynamic range can be provided by expanding the dynamic range by the amplifier using the differential amplifier as in the present embodiment, without increasing the chip area. The same can be applied to subsequent embodiments.

The switching device (offset controller) 415 inputs different reference voltages VC0R1 and VC0R2 in the first mode and in the second mode, respectively, into the input terminal (+) of the differential amplifier 408 and thereby changes the output offset voltage of the operational amplifier 408.

### Second Embodiment

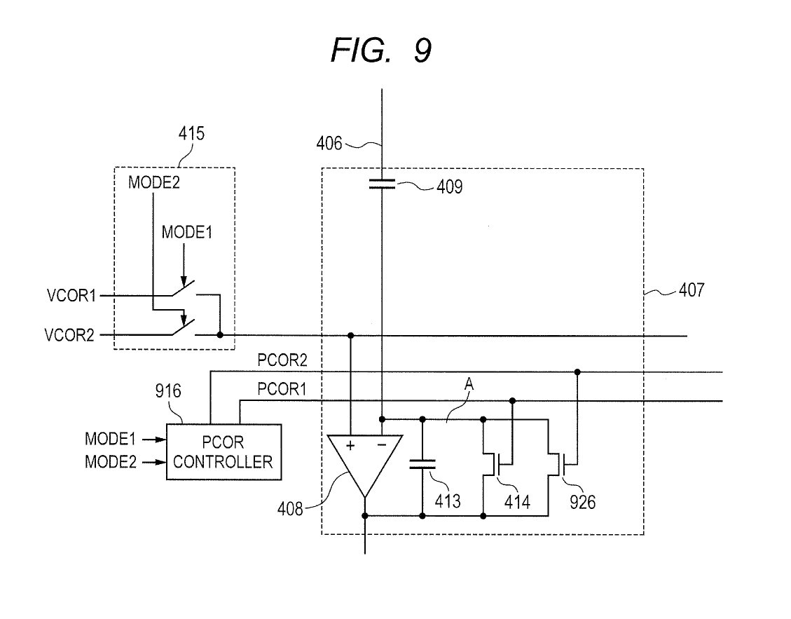

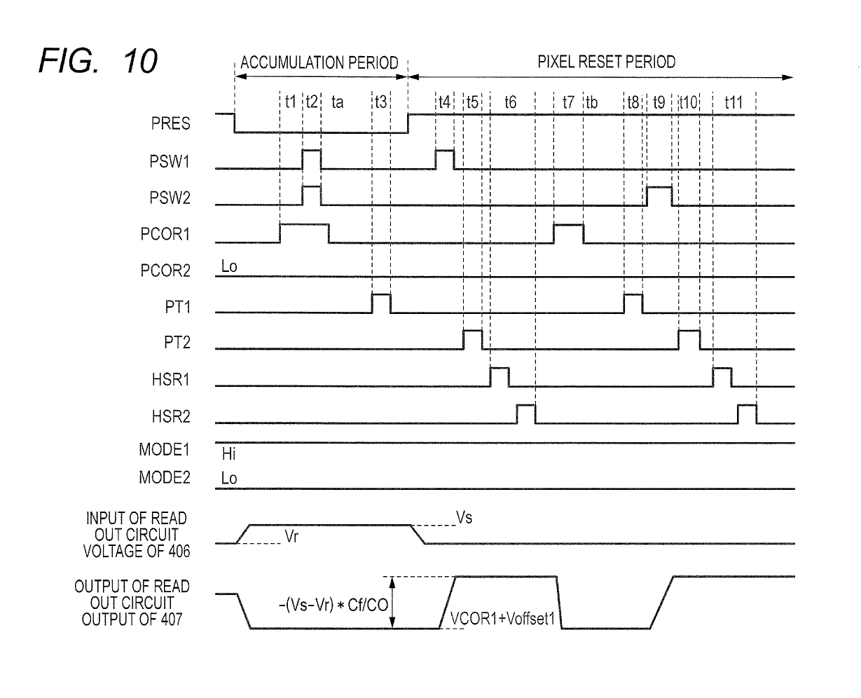

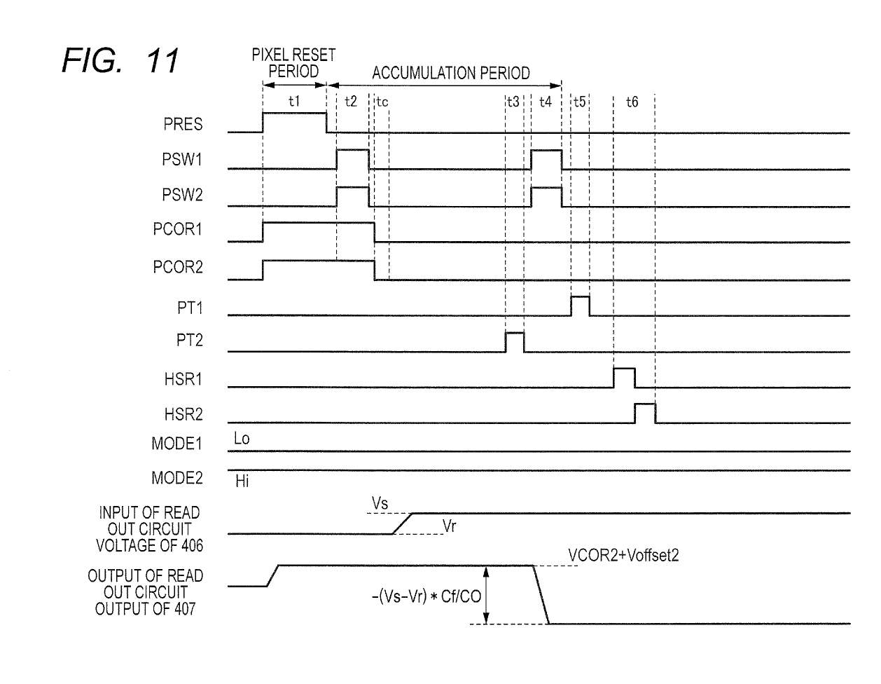

FIG. 9 is a view illustrating a configuration example of a solid-state imaging apparatus which has a readout circuit 407 according to a second embodiment of the present invention. FIG. 10 is a timing chart illustrating an operation example in a first mode of the solid-state imaging apparatus in FIG. 9, and FIG. 11 is a timing chart illustrating an operation example in a second mode of the solid-state imaging apparatus in FIG. 9. Hereafter, a point will be described in which the present embodiment is different from the first embodiment. In the readout circuit 407 in FIG. 9, switches 411 and 412 and an input capacitor 410 are omitted for simplification of description compared to the readout circuit 407 in FIG. 4. Incidentally, in the solid-state imaging apparatus of FIG. 9, an initializing switch 926 is added, and a PC0R controller 916 is provided in place of the PC0R controller 416 compared to the solid-state imaging apparatus of FIG. 4.

In the first mode, a first mode signal MODE1 becomes a high level and a second mode signal MODE2 becomes a low level, as in the timing chart in FIG. 10. Then, the PC0R controller 916 generates a signal PC0R1 which becomes a high level in a period containing periods t1, t2 and t7, and a signal PC0R2 that is fixed at a low level. On the other hand, in the second mode, the first mode signal MODE1 becomes a low level, and the second mode signal MODE2 becomes a high level, as in the timing chart in FIG. 11. Then, the PC0R controller 916 generates the same signals PC0R1 and PC0R2 both of which become a high level in periods t1 and t2. When a voltage to be lowered at a node (A) in the first mode is represented by −ΔVa1, and a voltage to be lowered at the node (A) in the second mode is represented by −ΔVa2, a relationship of ΔVa1<ΔVa2 holds. This is because a parasitic capacitance between gates of initializing switches 414 and 926 and the node (A) increases to twice the parasitic capacitance 706 in FIG. 7 by an operation of turning two initializing switches 414 and 926 on/off simultaneously in the second mode in FIG. 11, and the voltage to be lowered due to capacitive coupling also increases to twice the voltage to be lowered in FIG. 7. Based on the above reason, in the first mode, only the initializing switch 414 is turned on/off by the transition of a signal PC0R1, and in the second mode, two initializing switches 414 and 926 are turned on/off by the transition of two signals PC0R1 and PC0R2. A plurality of initializing switches 414 and 926 are provided. The number of the initializing switches 414 and 926 to be turned on is different between the first mode and the second mode. Thereby, the dynamic range of the output of the amplifier 408 is controlled to [Vthn+ΔVat×Cf/C0], and the dynamic range of the output can be widened.

Incidentally, the signal PC0R1 may be lowered in the periods to and tb in the first mode in FIG. 10, and the signals PC0R1 and PC0R2 may be lowered in the period tc in the second mode in FIG. 11, similarly to the first embodiment. Thereby, the fall periods ta, tb and tc may be controlled so as to satisfy a relationship of ta=tb>tc. Thereby, ΔVa2 of the second mode can be further increased and the output range can be further widened.

### Third Embodiment

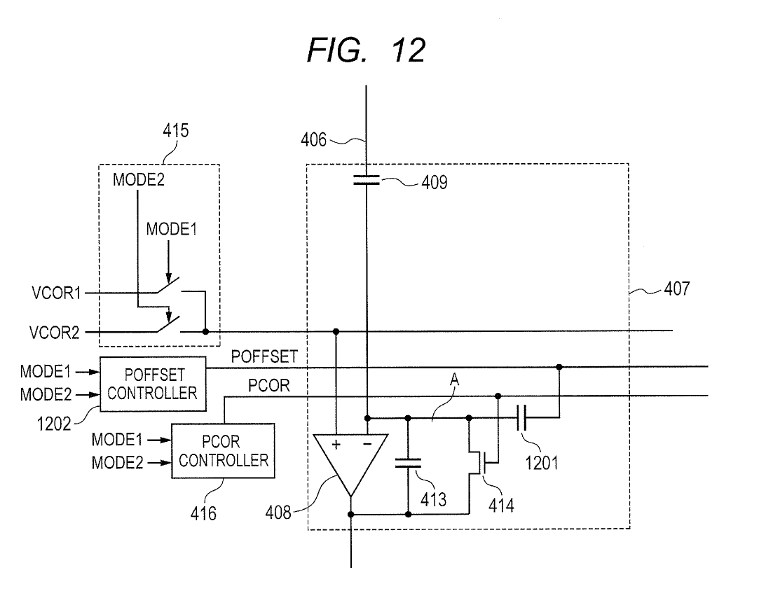

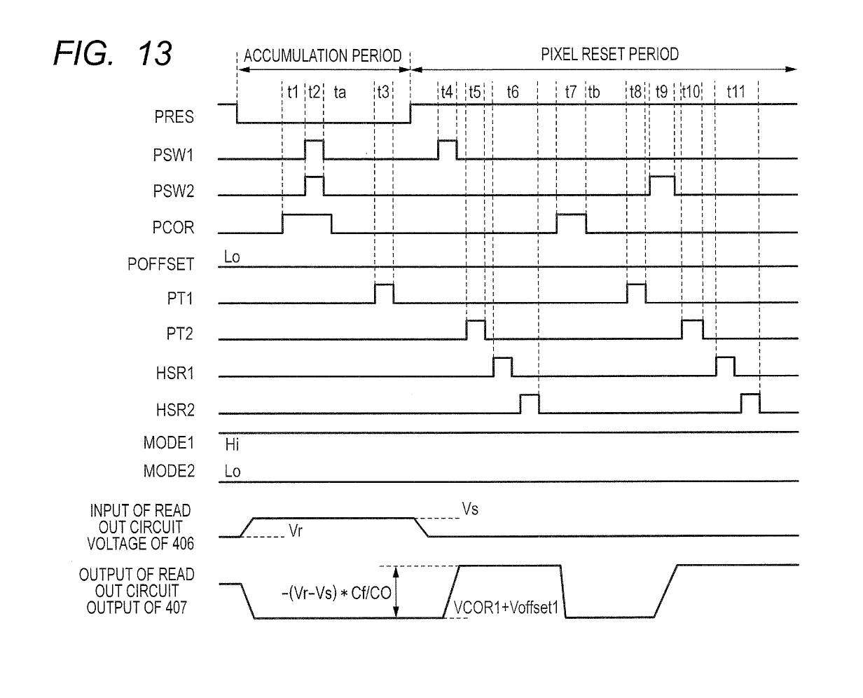

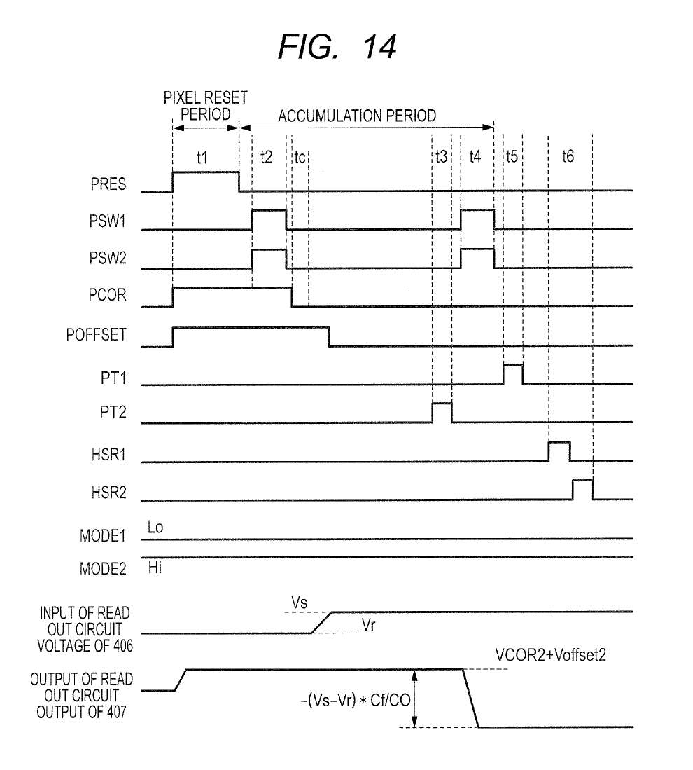

FIG. 12 is a view illustrating a configuration example of a solid-state imaging apparatus which has a readout circuit 407 according to a third embodiment of the present invention. FIG. 13 is a timing chart illustrating an operation example in the first mode of the solid-state imaging apparatus of FIG. 12, and FIG. 14 is a timing chart illustrating an operation example in the second mode of the solid-state imaging apparatus of FIG. 12. Hereafter, a point will be described in which the present embodiment is different from the first embodiment. In the readout circuit 407 in FIG. 12, the switches 411 and 412 and the input capacitor 410 are omitted for simplification of description compared to the readout circuit 407 in FIG. 4. Incidentally, in the solid-state imaging apparatus of FIG. 12, the capacitor 1201 and a POFFSET controller 1202 are added to the solid-state imaging apparatus of FIG. 4.

In the first mode, the first mode signal MODE1 becomes a high level, and the second mode signal MODE2 becomes a low level, as in the timing chart in FIG. 13. Then, the POFFSET controller 1202 generates the signal POFFSET which is fixed to a low level. Incidentally, the signal POFFSET may be fixed to a high level. In contrast to this, in the second mode, the first mode signal MODE1 becomes a low level, and the second mode signal MODE2 becomes a high level, as in the timing chart in FIG. 14. Then, the POFFSET controller 1202 outputs the signal POFFSET which becomes a high level in the period containing the periods t1 and t2. When a voltage to be lowered at a node (A) in the first mode is represented by −ΔVa1, and a voltage to be lowered at the node (A) in the second mode is represented by −ΔVa2, a relationship of ΔVa1<ΔVa2 holds. This is because the voltage at the node (A) is lowered due to the capacitive coupling of the capacitor 1201, by the transition of the signal POFFSET in the second mode. As described above, the signal POFFSET is fixed to a low level or a high level in the first mode, and the signal POFFSET is changed to the other level in the second mode. Thereby, the dynamic range of the output of the amplifier 408 becomes [Vthn+ΔVa2×Cf/C0], and the dynamic range of the output can be widened.

For information, it is also possible to lower the signal PC0R in the periods ta and tb in the first mode in FIG. 13, and to lower the signal PC0R in the period tc in the second mode in FIG. 14, similarly to the first embodiment. It is also possible to thereby control the fall periods ta, tb and tc of the signal PC0R so as to satisfy the relationship of ta=tb>tc. Thereby, ΔVa2 of the second mode can be further increased and the output range can be widened.

### Fourth Embodiment

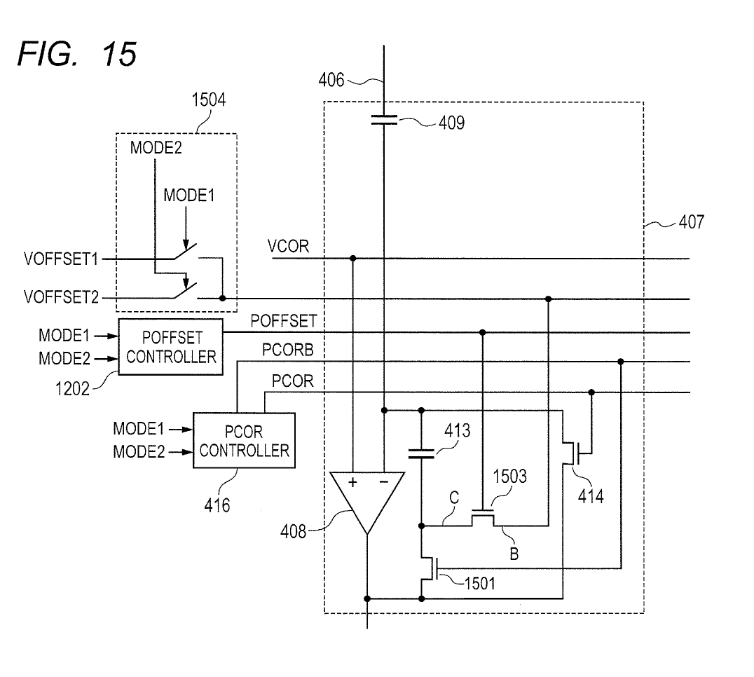

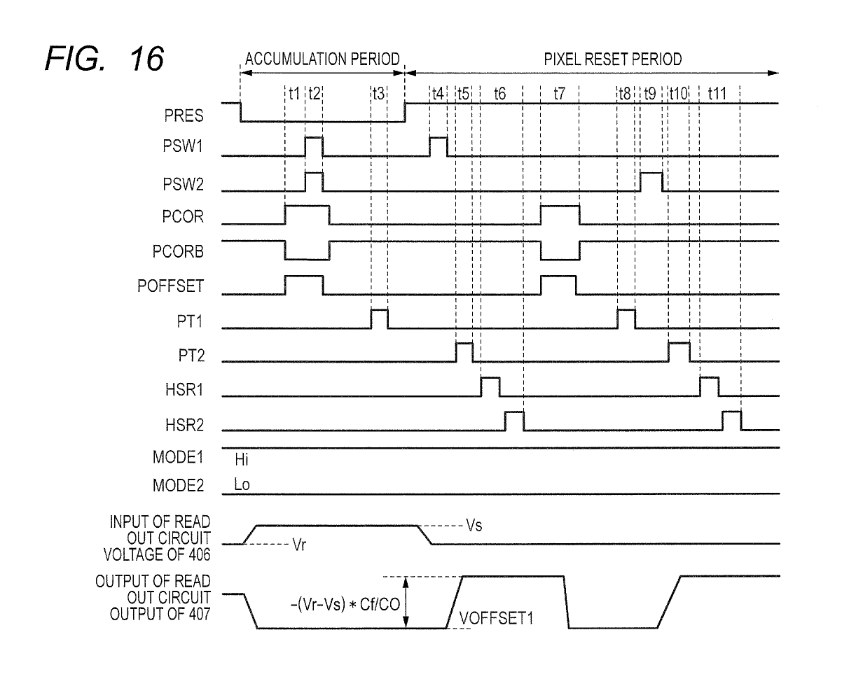

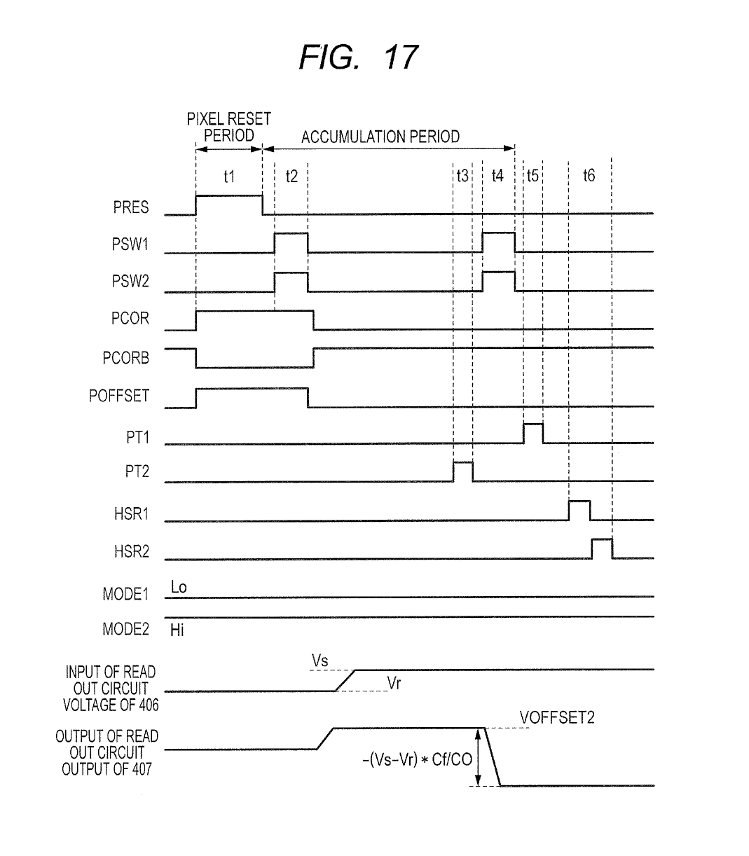

FIG. 15 is a view illustrating a configuration example of a solid-state imaging apparatus which has a readout circuit 407 according to a fourth embodiment of the present invention. FIG. 16 is a timing chart illustrating an operation example in the first mode of the solid-state imaging apparatus of FIG. 15, and FIG. 17 is a timing chart illustrating an operation example in the second mode of the solid-state imaging apparatus of FIG. 15. Hereafter, a point will be described in which the present embodiment is different from the first embodiment. In the readout circuit 407 in FIG. 15, the switches 411 and 412 and the input capacitor 410 are omitted for simplification of description compared to the readout circuit 407 in FIG. 4. Incidentally, in the solid-state imaging apparatus of FIG. 15, the switches 1501 and 1503, a switching device 1504 of VOFFSET and the POFFSET controller 1202 are added to the solid-state imaging apparatus of FIG. 4. The POFFSET controller 1202 is similar to the POFFSET controller 1202 in FIG. 12. The PC0R controller 416 outputs the signal PC0R and its inversion signal PC0RB. Input reference voltage VC0R is input into the input terminal (+) of the amplifier 408.

In the first mode, the first mode signal MODE1 becomes a high level and the second mode signal MODE2 becomes a low level, as in the timing chart in FIG. 16. Then, the switching device 1504 outputs an offset voltage VOFFSET1. In the period t1 to t2, the signal POFFSET becomes a high level, the switch 1503 is turned on, and the offset voltage VOFFSET1 is applied to a node (C). In the period, the signal PC0R is in a high level, the initializing switch 414 is turned on, the signal PC0RB is in a low level, the switch 1501 is off, and the voltage of the amplifier is in a clamped state. After the period t2, the signal POFFSET becomes a low level, and the switch 1503 is turned off. After that, the signal PC0RB becomes a high level, the switch 1501 is turned on, the signal PC0R becomes a low level, and the initializing switch 414 is turned off. Then, the offset voltage VOFFSET1 appears at an output terminal of the amplifier 408.

In the second mode, the first mode signal MODE1 becomes a low level and the second mode signal MODE2 becomes a high level, as in the timing chart in FIG. 17. Then, the switching device 1504 outputs an offset voltage VOFFSET2. In the period t1 to t2, the signal POFFSET becomes a high level, the switch 1503 is turned on, and the offset voltage VOFFSET2 is applied to the node (C). In the period, the signal PC0R is in a high level, the initializing switch 414 is turned on, the signal PC0RB is in a low level, the switch 1501 is off, and the voltage of the amplifier is in a clamped state. After the period t2, the signal POFFSET becomes a low level, and the switch 1503 is turned off. After that, the signal PC0RB becomes a high level, the switch 1501 is turned on, the signal PC0R becomes a low level, and the initializing switch 414 is turned off. Then, the offset voltage VOFFSET2 appears at an output terminal of the amplifier 408.

In the present embodiment, a clamp voltage of the output of the amplifier 408 is not determined by the input reference voltage VC0R, but the offset voltage VOFFSET1 or VOFFSET2 is written in the output terminal of the feedback capacitor 413, in the state in which the voltage of the amplifier is clamped. Thereby, the output offset voltage can be determined. The switching device (offset controller) 1504 applies the different offset voltages VOFFSET1 and VOFFSET2 in the first mode and the second mode, respectively, to a feedback capacitor 413, while the initializing switch 414 is turned on. In the first mode, the dynamic range can be expanded by the setting of VC0R>VOFFSET1. In the second mode, the dynamic range can be expanded by the setting of VC0R<VOFFSET2. In the first mode, the dynamic range can be expanded by the value of [VC0R−VOFFSET1] compared to the case where the output offset is determined by the input reference voltage VC0R. As well, in the second mode, the dynamic range can be expanded by the value of [VOFFSET2−VC0R].

### Fifth Embodiment

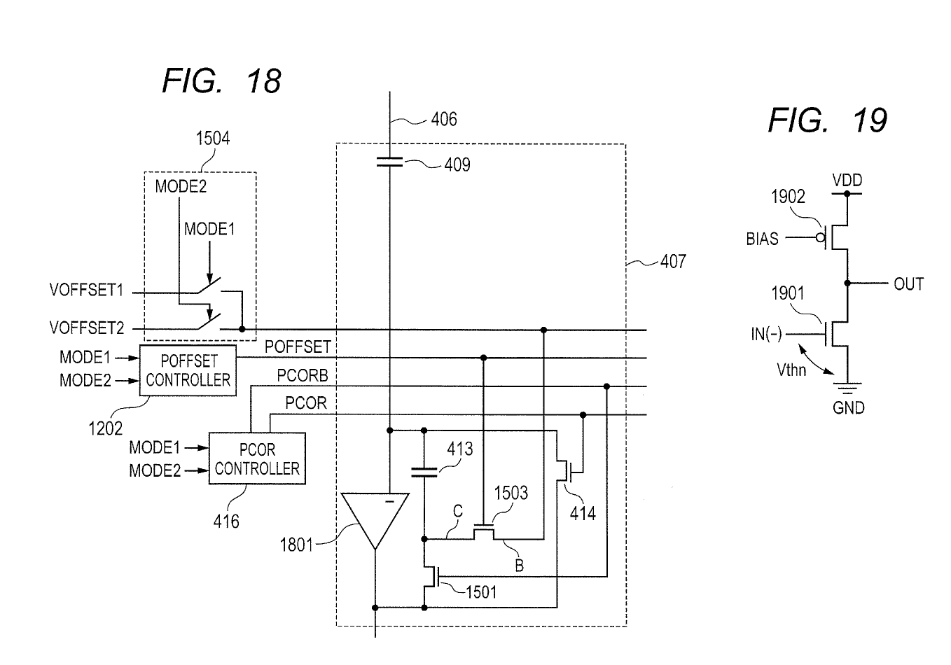

FIG. 18 is a view illustrating a configuration example of a solid-state imaging apparatus which has a readout circuit 407 according to a fifth embodiment of the present invention. Hereafter, a point will be described in which the present embodiment is different from the fourth embodiment. In the readout circuit 407 in FIG. 18, the switches 411 and 412 and the input capacitor 410 are omitted for simplification of description compared to the readout circuit 407 in FIG. 4. Incidentally, in the solid-state imaging apparatus of FIG. 18, the amplifier 1801 is provided in place of the amplifier 408 in the solid-state imaging apparatus of FIG. 15. The amplifier 1801 is a common source type amplifier having no input terminal (+). Because the amplifier 1801 has no input terminal (+), there is no input reference voltage VC0R.

FIG. 19 is a circuit diagram illustrating a configuration example of the amplifier 1801 in FIG. 18. An NMOS transistor 1901 and a PMOS transistor 1902 are shown. A constant voltage BIAS is applied to a gate of the transistor 1902, and the transistor 1902 functions as a constant current load. A gate of the transistor 1901 is an input terminal (−) and is connected to an input capacitor 409 in FIG. 18. In the transistor 1901, the drain is connected to an output terminal OUT and the source is connected to the ground potential node. When the common source type amplifier 1801 is used and the input terminal (−) and the output terminal are simply short-circuited to be initialized, the offset of the output is determined almost by a threshold voltage Vthn of the transistor 1901.

Accordingly, when the common source type amplifier 1801 is used in the readout circuit 407 in which an input order of a photo signal Vs and a reset signal Vr is switched, for instance, between the first and second modes, an appropriate dynamic range is not occasionally obtained. Usually VDD is much larger than Vthn, and accordingly when an output voltage of the amplifier 1801 corresponding to a difference of Vr−Vs rises as in the first mode, there are few problems in a dynamic range. However, when the output voltage of the amplifier 1801 corresponding to the difference of Vs−Vr descends as in the second mode, a problem occurs in the dynamic range. Then, in the fifth embodiment, an output offset voltage VOFFSET1 or VOFFSET2 is switched between the first and second modes, as in FIG. 18. A timing chart of the first mode is the same as that in FIG. 16 and a timing chart of the second mode is the same as that in FIG. 17. Thus, the timing charts are not different from those in the fourth embodiment.

In the first mode, the first mode signal MODE1 becomes a high level and the second mode signal MODE2 becomes a low level, as in the timing chart in FIG. 16. Then, the switching device 1504 outputs the offset voltage VOFFSET1. In the period t1 to t2, the signal POFFSET becomes a high level, the switch 1503 is turned on, and the offset voltage VOFFSET1 is applied to a node (C). In the period, the signal PC0R is in a high level, the initializing switch 414 is turned on, the signal PC0RB is in a low level, the switch 1501 is turned off, and the voltage of the amplifier is in a clamped state. After the period t2, the signal POFFSET becomes a low level, and the switch 1503 is turned off. After that, the signal PC0RB becomes a high level, the switch 1501 is turned on, the signal PC0R becomes a low level and the initializing switch 414 is turned off. Then, the offset voltage VOFFSET1 appears at an output terminal of the amplifier 1801.

In the second mode, the first mode signal MODE1 becomes a low level and the second mode signal MODE2 becomes a high level, as in the timing chart in FIG. 17. Then, the switching device 1504 outputs the offset voltage VOFFSET2. In the period t1 to t2, the signal POFFSET becomes a high level, the switch 1503 is turned on, and the offset voltage VOFFSET2 is applied to the node (C). In the period, the signal PC0R becomes a high level, the initializing switch 414 is turned on, the signal PC0RB becomes a low level, the switch 1501 is turned off, and the voltage of the amplifier is in a clamped state. After the period t2, the signal POFFSET becomes a low level, and the switch 1503 is turned off. After that, the signal PC0RB becomes a high level, the switch 1501 is turned on, the signal PC0R becomes a low level and the initializing switch 414 is turned off. Then, the offset voltage VOFFSET2 appears at the output terminal of the amplifier 1801.

In the present embodiment, a clamp voltage of the output of the amplifier 1801 is not determined by the threshold voltage Vthn of the transistor 1901, but the offset voltage VOFFSET1 or VOFFSET2 is written in the output terminal of a feedback capacitor 413, in the state in which the voltage of the amplifier is clamped. Thereby, the output offset voltage can be determined. In the first mode, the dynamic range can be expanded by the setting of Vthn>VOFFSET1. In the second mode, the dynamic range can be expanded by the setting of Vthn<VOFFSET2. In the first mode, the dynamic range can be expanded by the value of [Vthn−VOFFSET1] compared to the case where the output offset is determined by the threshold voltage Vthn. As well, in the second mode, the dynamic range can be expanded by the value of [VOFFSET2−Vthn].

Note that the above embodiments are merely examples how the present invention can be practiced, and the technical scope of the present invention should not be restrictedly interpreted by the embodiments. In other words, the present invention can be practiced in various ways without departing from the technical concept or main features of the invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-156611, filed on Jul. 12, 2012, which is hereby incorporated by reference herein in its entirety.

What is claimed is:

1. A readout circuit comprising:
an amplifier; and
an offset controller configured to set an output offset voltage of the amplifier, wherein
the readout circuit operates in first and second modes,
in the first mode, a first voltage is input to the amplifier, and thereafter a second voltage lower than the first voltage is input to the amplifier,
in the second mode, a third voltage is input to the amplifier, and thereafter inputs a fourth voltage lower than the third voltage is input to the amplifier, and
the offset controller switches the output offset voltage of the amplifier, between the first and second modes.

2. The readout circuit according to claim 1, wherein
the amplifier has a clamping unit configured to clamp the first voltage in the first mode, and to clamp the third voltage in the second mode.

3. The readout circuit according to claim 1, wherein
the amplifier is a differential amplifier or a common source type amplifier.

4. The readout circuit according to claim 2, wherein
the clamping unit has
an input capacitor configured to input a signal by capacitive coupling to an input terminal of the amplifier;
an initializing switch configured to short circuit between the input terminal and an output terminal of the amplifier; and
a feedback capacitor arranged between the input terminal and the output terminal of the amplifier.

5. The readout circuit according to claim 2, wherein
in the first mode, the initializing switch is turned on when the first voltage is inputted to the input capacitor, and
in the second mode, the initializing switch is turned on when the third voltage is inputted to the input capacitor.

6. The readout circuit according to claim 4, wherein
a transition period of a control signal for switching from on to off of the initializing switch in the first mode is different from a transition period of the control signal for switching from on to off of the initializing switch in the second mode.

7. The readout circuit according to claim 1, wherein
the amplifier is a differential amplifier, and
a reference voltage input to the differential amplifier from the offset controller in the first mode is different from a reference voltage input to the differential amplifier from the offset controller in the second mode.

8. The readout circuit according to claim 1, wherein
a plurality of the initializing switches are provided, and
a number of the initializing switches turned on in the first mode is different from a number of the initializing switches turned on in the second mode.

9. The readout circuit according to claim 4, wherein
the offset controller applies different offset voltages to the feedback capacitor in an on state of the initializing switch in the first mode and in an on state of the initializing switch in the second mode.

10. A solid-state imaging apparatus comprising:
a readout circuit according to claim 1; and
a pixel configured to generate a signal by a photoelectric conversion, wherein
the signal generated by the pixel is input to the readout circuit.

11. The solid-state imaging apparatus according to claim 10, further comprising:
an output amplifier configured
to output, in the first mode, a difference between an output voltage from the amplifier at a time of inputting the first voltage and an output voltage from the amplifier at a time of inputting the second voltage, and
to output, in the second mode, a difference between an output voltage from the amplifier at a time of inputting the third voltage and an output voltage from the amplifier at a time of inputting the fourth voltage.

12. A method of driving a readout circuit comprising: an amplifier; wherein the method comprises:
operating the readout circuit in first and second modes;
in the first mode, inputting, to the amplifier, a first voltage, and thereafter inputting a second voltage lower than the first voltage;
in the second mode, inputting, to the amplifier, a third voltage, and thereafter inputting a fourth voltage lower than the third voltage, and
switching the output offset voltage of the amplifier, in the first and second modes.

13. The method according to claim 12, wherein
the amplifier has a clamping unit configured to clamp the first voltage in the first mode, and to clamp the third voltage in the second mode.

14. The method according to claim 12, wherein
the clamping unit has
an input capacitor configured to input a signal by capacitive coupling to an input terminal of the amplifier;
an initializing switch configured to short circuit between the input terminal and an output terminal of the amplifier; and
a feedback capacitor arranged between the input terminal and the output terminal of the amplifier, and
applying different offset voltages to the feedback capacitor in an on state of the initializing switch in the first mode and in the on state of the initializing switch in the second mode.
